(19) United States
(12) Patent Application Publication
(10) Pub. No.: US 2022/0076950 A1
(43) Pub. Date: Mar. 10, 2022

(54) SEMICONDUCTOR DEVICE WITH A GROUP-III OXIDE ACTIVE LAYER

(71) Applicant: KING ABDULLAH UNIVERSITY OF SCIENCE AND TECHNOLOGY, Thuwal (SA)

(72) Inventors: Xiaohang LI, Thuwal (SA); Che-Hao LIAO, Thuwal (SA)

(21) Appl. No.: 17/417,788

(22) PCT Filed: Jan. 14, 2020
(86) PCT No.: PCT/IB2020/050268

§ 371 Date: Jun. 24, 2021

Related U.S. Application Data
(60) Provisional application No. 62/799,140, filed on Jan. 31, 2019.

(51) Int. Cl. H01L 21/02; H01L 29/24

(52) U.S. Cl. CPC H01L 21/02414; H01L 21/02483; H01L 29/24; H01L 21/02266; H01L 21/02565

(57) ABSTRACT

A method for forming a semiconductor device with a group-III oxide active layer including at least two group-III materials is provided. A group-III oxide substrate is provided and a group-III oxide active layer including at least one group-III material on the group-III oxide substrate is formed on the group-III oxide substrate. A group-III material in the group-III oxide substrate is different from the at least one group-III material in the group-III oxide active layer. The group-III oxide active layer including at least one group-III material and the group-III oxide substrate are annealed at a temperature greater than or equal to 1,000° C. so that the group-III material in the group-III oxide substrate diffuses into the group-III oxide active layer to form the group-III oxide active layer including the at least two group-III materials.

### CROSS-REFERENCE TO RELATED APPLICATIONS

This application claims priority to U.S. Provisional Patent Application No. 62/799,140, filed on Jan. 31, 2019, entitled “METHOD TO TRANSFORM BINARY OXIDE MATERIAL INTO TERNARY AND QUATERNARY OXIDE MATERIALS WITH GROUP-III MATERIAL BY HIGH TEMPERATURE ANNEALING,” the disclosure of which is incorporated herein by reference in its entirety.

### BACKGROUND

### Technical Field

Embodiments of the disclosed subject matter generally relate to semiconductor devices having a group-III oxide active layer comprising at least two group-III materials and methods for forming such devices so that the content of the group-III materials of the active layer can be selected to achieve a desired content of the group-III materials.

### Discussion of the Background

Group-III oxides are particularly useful materials for use as an active layer in a number of different types of semiconductor devices, including power transistors and photodetectors. Different group-III materials exhibit different effects on the active layer. For example, it is common to form power transistors, such as power metal-insulator-semiconductor field-effect transistors (MISFETs) having an active layer comprising gallium oxide (Ga₂O₃). One study demonstrated that a photodetector with a gallium oxide active layer can produce higher photocurrent and exhibit an improved response by adding aluminum so that the active layer comprises aluminum gallium oxide ((AlₓGa₁₋ₓ)₂O₃).

One conventional way of forming an aluminum gallium oxide active layer on a substrate is using pulsed laser deposition (PLD) in which a target having a particular composition of aluminum, gallium, and oxygen is subjected to a pulsed laser, which causes the materials of the target to rise and be deposited on a substrate. The amount of each of aluminum, gallium, and oxygen in the target is predetermined and corresponds to the desired amount of each of these materials in the active layer formed by pulsed laser deposition. Thus, any error in the composition of aluminum and gallium in the target will result in the active layer formed using pulsed laser deposition not having the corresponding desired amount of aluminum and gallium, and thus the resulting semiconductor device may not operate as intended, e.g., it may be less efficient and/or less responsive. Further, the conventional technique limits customizability of the composition of the active layer because each different composition requires creating targets having corresponding different compositions. Moreover, the conventional pulsed laser deposition technique can result in an active layer having crystal defects, which can reduce the efficiency and responsiveness of the active layer.

Thus, there is a need for a method for forming a semiconductor device having a group-III oxide active layer comprising at least two group-III materials that provides greater control over the amount of one of the at least two group-III materials in the active layer in a simpler manner than conventional pulsed laser deposition techniques and forms group-III oxide active layer comprising at least two group-III materials with improved crystal quality compared to active layers formed with conventional pulsed laser deposition techniques.

### SUMMARY

According to an embodiment, there is a method for forming a semiconductor device with a group-III oxide active layer comprising at least two group-III materials. A group-III oxide substrate is provided and a group-III oxide active layer comprising at least one group-III material is formed on the group-III oxide substrate. A group-III material in the group-III oxide substrate is different from the at least one group-III material in the group-III oxide active layer. The group-III oxide active layer comprising at least one group-III material and the group-III oxide substrate are annealed at a temperature greater than or equal to 1,000° C. so that the group-III material in the group-III oxide substrate diffuses into the group-III oxide active layer to form the group-III oxide active layer comprising the at least two group-III materials.

According to another embodiment, there is a semiconductor device with a group-III oxide active layer comprising at least two group-III materials. The semiconductor device comprises a group-III oxide substrate, a group-III oxide active layer comprising the at least two group-III materials and arranged on the group-III oxide substrate. One of the at least two group-III materials of the group-III oxide active layer is a same group-III material as in the group-III oxide substrate. An inter-diffusion region is arranged between the group-III oxide substrate and the group-III oxide active layer.

According to a further embodiment, there is a method for forming a semiconductor device with a group-III oxide active layer comprising at least two group-III materials. An amount of one of the two group-III materials for the group-III oxide active layer comprising the at least two group-III materials is determined. An annealing temperature is determined based on the determined amount of the one of the at least two group-III materials. A group-III oxide active layer comprising at least one group-III material is formed on a group-III oxide substrate. The group-III oxide substrate includes the one of the at least two group-III materials. The group-III oxide active layer comprising at least one group-III material and the group-III oxide substrate are annealed at the determined annealing temperature so that the one of the at least two group-III materials in the group-III oxide substrate diffuses into the group-III oxide active layer comprising at least one group-III material to form the group-III oxide active layer comprising the at least two group-III materials. The determined annealing temperature is greater than or equal to 1,000° C.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a flow diagram of a method for forming a semiconductor device having a group-III oxide active layer comprising at least two group-III materials according to embodiments;

FIGS. 2A-2D are schematic diagrams of a method for forming a semiconductor device having a group-III oxide active layer comprising at least two group-III materials according to embodiments;

FIG. 3 is cross-sectional transmission electron microscopy image of a semiconductor device having an aluminum group-III oxide active layer according to embodiments;

FIG. 4 is a flow diagram of a method for forming a semiconductor device having a group-III oxide active layer comprising at least two group-III materials according to embodiments; and

FIG. 5 is a graph illustrating the annealing temperature dependence of the aluminum composition according to embodiments.

### DETAILED DESCRIPTION

The following description of the exemplary embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to the terminology and structure of semiconductor devices having a group-III oxide active layer comprising at least two group-II II materials.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

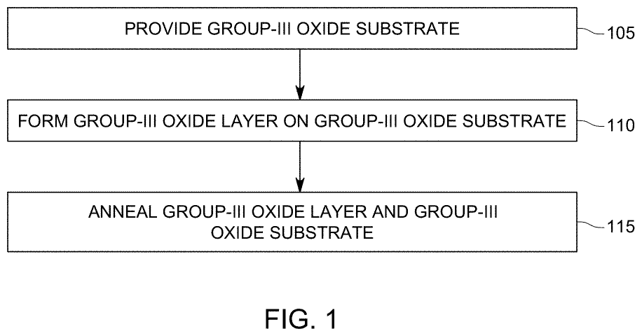

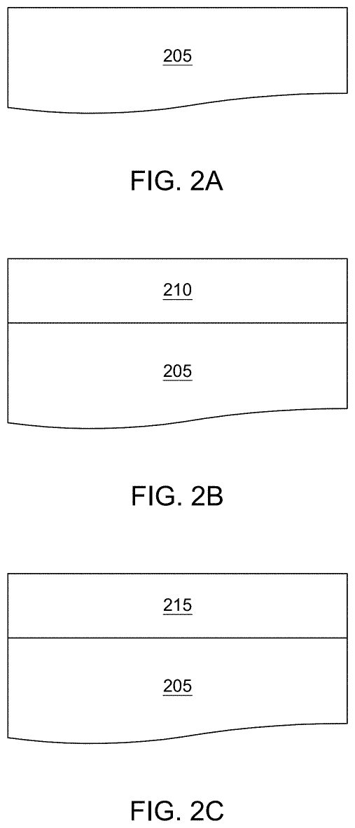

A method for forming a semiconductor device having a group-III oxide active layer comprising at least two group-III materials according to embodiments will now be described in connection with FIGS. 1 and 2A-2D. Turning first to FIGS. 1 and 2A, a group-III oxide substrate 205 is provided (step 105). As illustrated in FIG. 2B, a group-III oxide active layer comprising at least one group-III material 210 is formed on the group-III oxide substrate 205 (step 110). The group-III material in the group-III oxide substrate 205 is different from the at least one group-III material in the group-III oxide active layer 210. The group-III oxide active layer comprising at least one group-III material 210 and the group-III oxide substrate 205 are then annealed at a temperature greater than or equal to 1,000° C. so that the group-III material in the group-III oxide substrate 205 diffuses into the group-III oxide active layer comprising at least one group-III material 210 to form a group-III oxide layer active layer comprising at least two group-III materials 215, which is illustrated in FIG. 2C (step 115).

The group-III oxide active layer comprising at least one group-III material 210 can be alpha-, beta-, or epsilon-phase. Similarly, group-III oxide active layer comprising at least two group-III materials 215 can be alpha-, beta-, or epsilon-phase. However, in practice, the high-temperature annealing will, in many cases, result in a beta-phase because this is the most stable phase.

The group-III material in the group-III oxide substrate 205 can be any group-III material, including aluminum, gallium, indium, or boron. For example, the group-III oxide substrate 205 can be comprised of aluminum oxide (Al₂O₃), i.e., sapphire, or gallium oxide (Ga₂O₃). The high temperature annealing causes the group-III material and oxide of the group-III oxide substrate 205 to diffuse into the group-III oxide active layer comprising at least one group-III material 210 to form a group-III oxide active layer comprising at least two group-III materials 215. It has been recognized that there is a dependence between the annealing temperature and the amount of the group-III material that diffuses from the group-III oxide substrate 205 into the group-III oxide layer active layer comprising at least one group-III material 210, the details of which will be addressed below. In general, the annealing temperature can be greater than or equal to 1,000° C. and less than or equal to 1,500° C. The annealing also improves the crystal quality of the group-III oxide layer active layer comprising at least two group-III materials 215. Based on experiments, it was found that the crystal quality of a beta-phase aluminum group-III oxide layer active layer 215 did not improve much past three hours of annealing, and thus the annealing can be performed for three hours.

The annealing can be performed with ambient air and the group-III oxide active layer comprising at least one group-III material 210 can be formed using pulsed laser deposition (PLD). The method is applicable to a variety of different compositions of group-III materials and the composition can be, for example, a binary composition including a single group-III material or can be a ternary composition including two group-III materials. The group-III material of the group-III oxide active layer comprising at least one group-III material 210 can be aluminum, gallium, indium, or boron. It should be recognized that at least one of the group-III materials of the group-III oxide substrate 205 is a different group-III material than at least one of the group-III materials of the group-III oxide active layer comprising at least one group-IIII material 210. For example, the group-III oxide substrate 205 can comprise aluminum oxide (Al₂O₃), gallium oxide (Ga₂O₃), indium oxide (In₂O₃), or boron oxide (B₂O₃), and the group-III oxide active layer comprising at least one group-II II material 210 can be the other one of Al₂O₃, Ga₂O₃, In₂O₃, and B₂O₃. Thus, after annealing, the group-III oxide layer active layer 215 can be an aluminum gallium oxide ((AlGa)₂O₃) active layer, an aluminum indium oxide ((AlIn)₂O₃) active layer, an aluminum boron oxide ((AlB)₂O₃) active layer, an aluminum gallium indium oxide ((AlGaIn)₂O₃) active layer, an aluminum gallium boron oxide ((AlGaB)₂O₃) active layer, an aluminum indium boron ((AlInB)₂O₃) active layer, a gallium indium oxide ((GaIn)₂O₃) active layer, a gallium boron oxide ((GaB)₂O₃) active layer, a boron indium oxide ((BIn)₂O₃) active layer, a gallium indium boron oxide ((GaInB)₂O₃) active layer, etc.

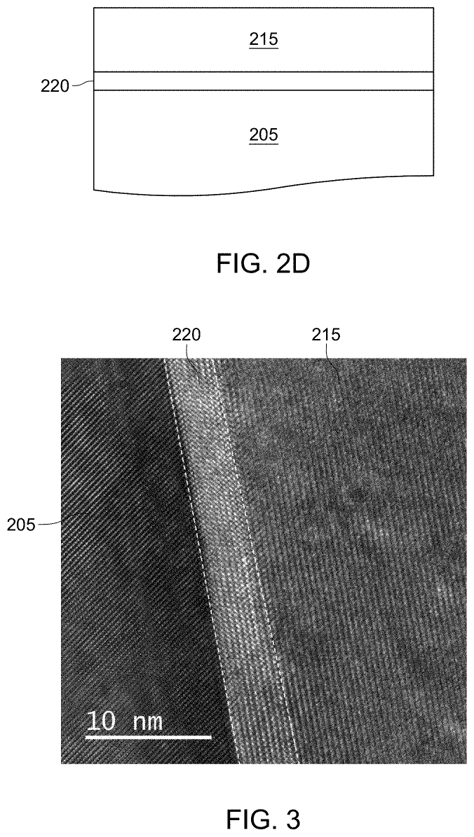

The diffusion occurring during the annealing forms an inter-diffusion region between the group-III oxide substrate 205 and the group-III oxide active layer comprising at least two group-III materials 215. A non-limiting example will now be presented in connection with FIGS. 2D and 3, which illustrate a semiconductor device with a sapphire substrate 205, a beta-phase oxide layer active layer 215 comprising aluminum and at least one additional group-III material arranged on the sapphire substrate 205, and an inter-diffusion region 220 between the sapphire substrate 205 and the beta-phase aluminum group-III oxide active layer comprising aluminum and at least one additional group-III material 215. (In FIG. 3, the two dashed lines were added to the TEM image to highlight the approximate boundaries of the inter-diffusion region 220). The inter-diffusion region includes constituent materials of both sapphire (i.e., aluminum and oxide) and the group-III oxide. It should be recognized that the description in this non-limiting example applies equally to substrates 205 and group-III oxide active layers 215 having different constituent materials, the combinations of which are described above.

It should be recognized that in FIGS. 2A-2D, as is conventional practice in the art, the lower portion of the sapphire substrate 205 is non-uniform to indicate that the thickness of the sapphire substrate 205 continues beyond the non-uniform lower portion. Regardless, FIGS. 2A-2D are not to scale, and therefore, these figures are not illustrative of the actual thicknesses of any of the layers or of the substrate.

The semiconductor device comprising the group-III oxide substrate 205 and the group-III oxide active layer comprising at least two group-III materials 215 can be used to form, for example, a photodetector or power transistor, such as a metal-insulator-semiconductor field effect transistor (MISFET). Returning to the non-limiting example of a beta-phase aluminum gallium oxide active layer 215 formed on a sapphire substrate, by adjusting the amount of aluminum incorporated into a group-III oxide active layer to form a ternary alloy, e.g., β-(AlGa)₂O₃, the cut-off wavelength of a deep-ultra-violet (UV) photodetector can be adjusted. It will be recognized that the scaling of a power transistor, such as a MISFET, is benefited by a higher breakdown voltage of the active layer with wider energy bandgap engineering, which can be achieved using the aluminum group-III oxide active layer. This non-limiting example applies equally to other substrates 205 and group-III oxide active layers 215 having different constituent materials, the combinations of which are described above

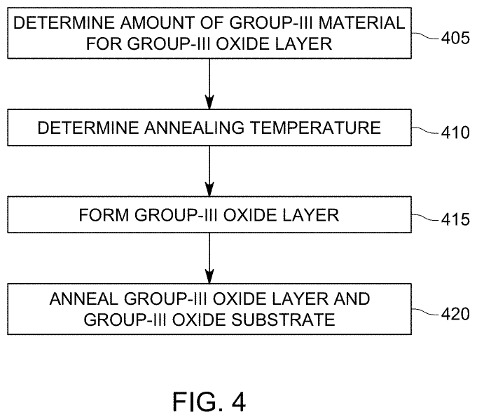

As mentioned above, it has been recognized that there is a correlation between the annealing temperature and the amount of the group-III material that diffuses from the group-III oxide substrate 205. A method for forming a semiconductor device with a group-III oxide active layer comprising at least two group-III materials 215 using this correlation is illustrated in FIG. 4. Initially, an amount of one of the two group-III materials for a group-III oxide active layer comprising the at least two group-III materials 215 is determined (step 405) and an annealing temperature is determined based on the determined amount of the one of the at least two group-III materials (step 410). The group III-oxide substrate 205 includes the one of the at least two group-III materials. The determination of an annealing temperature can be performed using a look-up table that correlates annealing temperature and aluminum composition in the active layer, an example of which is illustrated in Table 1 below, which was generated based on experiments in which the beta-phase group-III oxide active layer 210 was a gallium oxide (Ga₂O₃) layer. It will be recognized that similar tables can be generated for other compositions of the group-III oxide active layer 210, and these other tables will similarly show an increasing group-III material content that diffuses from the substrate 205 corresponding to increases in the annealing temperature.

TABLE 1

| | (−201) | (0006) | Δ(−201) | | |
|---|---|---|---|---|---|
| Annealing | β-Ga₂O₃ | Sapphire | β-Ga₂O₃ | Bandgap (Eg) | |
| temperature | peak | peak | peak shift | from Tauc plot | (AlₓGa₁₋ₓ)₂O₃X |
| As deposited | 18.95° | 41.68° | 0° | 4.9 eV | 0.00 |
| | | | (reference) | | |
| 1000° C. | 18.98° | 41.68° | +0.03° | 5.3 | 0.35 |
| 1100° C. | 19.13° | 41.68° | +0.18° | 5.8 | 0.58 |
| 1200° C. | 19.25° | 41.68° | +0.30° | 6.1 | 0.67 |
| 1300° C. | 19.33° | 41.68° | +0.38° | 6.2 | 0.72 |
| 1400° C. | 19.37° | 41.68° | +0.42° | 6.4 | 0.78 |
| 1500° C. | 19.43° | 41.68° | +0.48° | >6.4 | >0.78 |
| 1600° C. | N/A | 41.68° | N/A | N/A | N/A |

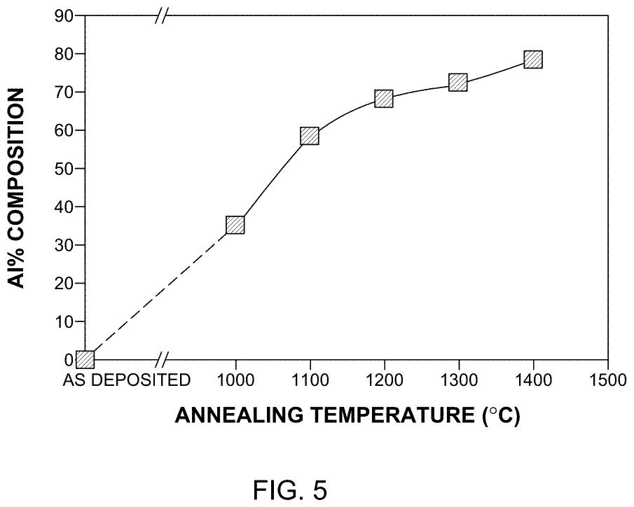

A graph formed using the data from this table is illustrated in FIG. 5. The data points on this graph can be used to extrapolate aluminum compositions corresponding to annealing temperatures between the 100° C. steps in Table 1. Alternatively, or additionally, the look-up table can be made more granular by measuring the aluminum concentration of the active layer at temperatures having a step size smaller than the 100° C. steps Table 1. Because the bandgap of the active layer depends upon the aluminum content of the active layer, the bandgap of the active layer is tunable based on the annealing temperature. It should be recognized that using an annealing temperature of 1300° C. or greater is particularly advantageous because it results in the active layer having an aluminum content that is greater than 70%, which covers the bandgap from 4.9 to 6.4 eV. Such a large bandgap tuning range of the aluminum group-III oxide active layer is advantageous for bandgap engineering and makes it feasible for a wider bandgap design of a photodetector or power device, which is difficult to achieved using other thin film deposition methods with an aluminum content greater than 70%.

Table 1 also includes data collected from testing identifying the (−201) β-Ga₂O₃ peak, the (0006) sapphire peak and the difference in the β-Ga₂O₃ peak between the deposited but not annealed gallium oxide active layer versus the annealed gallium oxide active layer that includes aluminum as the result of the annealing. These additional columns demonstrate that the annealing had little effect on the sapphire substrate but the β-Ga₂O₃ peak increased as the result of annealing due to the diffusion of aluminum into the active layer. These additional columns are included in Table 1 merely to demonstrate that aluminum from the sapphire substrate diffused into the active layer and these additional columns need not be part of a look-up table used to determine the annealing temperature to obtain a particular aluminum content in the active layer.

Returning to FIG. 4, a group-III oxide active layer comprising at least one group-III material 210 is formed on a group-III oxide substrate 205 (step 415). Finally, the group-III oxide active layer comprising at least one group-III material 210 and the group-III oxide substrate 205 are annealed at the determined annealing temperature so that the at least one of the at least two group-III materials in the group-III oxide substrate 205 diffuses into the group-III oxide active layer comprising at least one group-III material 210 to form a group-III oxide active layer comprising at least two group-III materials 215 (step 420). The determined annealing temperature is greater than or equal to 1,000° C.

Similar to the method discussed above in connection with FIGS. 1 and 2A-2D, the determined annealing temperature can be greater than or equal to 1,000° C. and less than or equal to 1,500° C., the annealing can be performed for three hours, and the group-III oxide active layer comprising at least one group-III material 210 is formed using pulsed laser deposition. The group-III oxide active layer comprising at least one group-III material 210 can be a binary composition including a single group-III material or is a ternary composition including two group-III materials. Finally, the group-III material is aluminum, gallium, indium, or boron.

The beta-phase gallium oxide active layers that were used to determine the aluminum content of the annealed active layer were also evaluated to determine the crystallinity of the annealed active layer, the results of which are reproduced in Table 2 below.

TABLE 2

| | | | | Crystalline |
|---|---|---|---|---|
| Annealing | RC FWHM | RC FWHM | AFM RMS | Domain Size |
| temperature | (°) | (arcsec) | (nm) | (nm) |
| As deposited | 2.510 | 9036 | 1.58 | 33.6 |
| 1000° C. | 2.250 | 8100 | 1.83 | 44.0 |
| 1100° C. | 2.364 | 8510 | 1.49 | 37.4 |
| 1200° C. | 1.490 | 5364 | 1.50 | 50.8 |
| 1300° C. | 0.914 | 3290 | 1.19 | 52.1 |
| 1400° C. | 0.410 | 1476 | 1.77 | 76.8 |
| 1500° C. | 0.150 | 540 | 8.13 | 88.3 |

As reflected in Table 2, as the annealing temperature increased the crystallinity of the active layer improved. The FWHM of the rocking curve reduces with increased annealing temperatures and the crystalline domain size also increases, which results in a better crystal quality. The AFM RMS value, which corresponds to the surface roughness of the aluminum group-III oxide active layer maintains a relatively stable value (<1.85 nm, below 1400° C.) until the annealing temperature reaches 1500° C. By selecting an appropriate annealing temperature and time, one can obtain either significantly improved crystal quality of the active layer or a relatively smooth surface on the top of the active layer. The improved crystallinity results in a more efficient and responsive active layer, and thus an improved semiconductor device.

A 50 nm thick gallium oxide active layer on a sapphire substrate was also evaluated using secondary ion mass spectrometry (SIM) to determine the depth profile of oxygen, gallium oxide, gallium, and aluminum. This evaluation included a 50 nm thick gallium oxide active layer on a sapphire substrate without any annealing (i.e., the layer directly after the pulsed laser deposition), annealing at 1000° C. for three hours in air, annealing at 1200° C. for three hours in air, and annealing at 1400° C. for three hours in air. The results of this evaluation demonstrated that under all annealing scenarios, aluminum was present throughout the active layer. It should be recognized that the diffusion caused by the annealing process reduces the thickness of the sapphire substrate and increases the thickness of the resulting aluminum gallium oxide active layer. Specifically, annealing at 1000° C. caused the 50 mn gallium oxide active layer to increase in thickness to 110 nm as the aluminum gallium oxide active layer, annealing at 1200° C. caused the 50 mn gallium oxide active layer to increase in thickness to 190 nm as the aluminum gallium oxide active layer, and annealing at 1400° C. caused the 50 mn gallium oxide active layer to increase in thickness to 250 nm as the aluminum gallium oxide active layer. It should be recognized that the sapphire substrate is of sufficient thickness (i.e., a thickness that is at least two times as thick as the original gallium oxide active layer) that the reduced thickness caused by diffusion during the annealing does not affect the electrical or physical characteristics of the sapphire substrate in a way that would be problematic to the intended purpose of the sapphire substrate in the resulting semiconductor device.

As will be appreciated from the discussion above, a correlation between annealing temperature and the amount of group-III material that diffuses from the group-III oxide substrate 205 into the group-III oxide active layer 210 has been discovered. This correlation is particularly advantageous because the group-III material content (and in turn the bandgap) can be controlled based upon annealing temperature and not based upon the composition of the target used for pulsed laser deposition. Further, this provides additional manufacturing flexibility because a device having a group-III oxide active layer comprising at least two group-III materials on a group-III oxide substrate can be produced in volume and then semiconductor devices with varying group-III material compositions in the active layer can be produced by varying the annealing temperature.

The disclosed embodiments provide semiconductor devices having a group-III oxide active layer comprising at least two group-III materials and methods for forming such devices. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A method for forming a semiconductor device with a group-III oxide active layer comprising at least two group-III materials, the method comprising:
providing a group-III oxide substrate;
forming a group-III oxide active layer comprising at least one group-III material on the group-III oxide substrate, wherein a group-III material in the group-III oxide substrate is different from the at least one group-III material in the group-III oxide active layer; and
annealing the group-III oxide active layer comprising at least one group-III material and the group-III oxide substrate at a temperature greater than or equal to 1,000° C. so that the group-III material in the group-III oxide substrate diffuses into the group-III oxide active layer to form the group-III oxide active layer comprising the at least two group-III materials.

2. The method of claim 1, wherein the temperature is greater than or equal to 1,000° C. and less than or equal to 1,500° C.

3. The method of claim 1, wherein the annealing is performed for three hours.

4. The method of claim 1, wherein the annealing is performed with ambient air.

5. The method of claim 1, wherein the group-III oxide active layer comprising the at least one group-III material is formed using pulsed laser deposition, PLD.

6. The method of claim 1, wherein the group-III oxide active layer comprising the at least one group-III material is a binary composition including a single group-III material.

7. The method of claim 1, wherein the group-III oxide active layer comprising the at least one group-III material is a ternary composition including two group-III materials.

8. The method of claim 1, wherein the at least one group-III material of the group-III oxide active layer comprising the at least one group-III material is aluminum, gallium, indium, or boron.

9. The method of claim 1, wherein the annealing forms an inter-diffusion region between the group-III oxide substrate and the group-III oxide active layer comprising at least two group-III materials.

10. A semiconductor device with a group-III oxide active layer comprising at least two group-III materials, the semiconductor device comprising:
a group-III oxide substrate;
a group-III oxide active layer comprising the at least two group-III materials and arranged on the group-III oxide substrate, wherein one of the at least two group-III materials of the group-III oxide active layer is a same group-III material as in the group-III oxide substrate; and
an inter-diffusion region between the group-III oxide substrate and the group-III oxide active layer.

11. The semiconductor device of claim 10, wherein the inter-diffusion region includes material from both the group-III oxide substrate and the group-III oxide active layer.

12. The semiconductor device of claim 10, wherein the at least two group-III materials are selected from the group of aluminum, gallium, indium, or boron.

13. The semiconductor device of claim 10, wherein the semiconductor device is a photodetector.

14. The semiconductor device of claim 10, wherein the semiconductor device is a metal-insulator-semiconductor field effect transistor.

15. A method for forming a semiconductor device with a group-III oxide active layer comprising at least two group-III materials, the method comprising:
determining an amount of one of the two group-III materials for the group-III oxide active layer comprising the at least two group-III materials;
determining an annealing temperature based on the determined amount of the one of the at least two group-III materials;
forming a group-III oxide active layer comprising at least one group-III material on a group-III oxide substrate, wherein the group-III oxide substrate includes the one of the at least two group-III materials; and
annealing the group-III oxide active layer comprising at least one group-III material and the group-III oxide substrate at the determined annealing temperature so that the one of the at least two group-III materials in the group-III oxide substrate diffuses into the group-III oxide active layer comprising at least one group-III material to form the group-III oxide active layer comprising the at least two group-III materials, wherein the determined annealing temperature is greater than or equal to 1,000° C.

16. The method of claim 15, wherein the determined annealing temperature is greater than or equal to 1,000° C. and less than or equal to 1,500° C.

17. The method of claim 15, wherein the annealing is performed for three hours.

18. The method of claim 15, wherein the group-III oxide active layer comprising at least one group-III material is formed using pulsed laser deposition, PLD.

19. The method of claim 15, wherein the group-III oxide active layer comprising the at least one group-III material is a binary composition including a single group-III material or is a ternary composition including two group-III materials.

20. The method of claim 15, wherein the at least one group-III material of the group-III oxide active layer is aluminum, gallium, indium, or boron.
